(19) United States
(12) Patent Application Publication
(10) Pub. No.: US 2014/0008212 A1
(43) Pub. Date: Jan. 9, 2014

(54) DEPOSITION APPARATUS AND DEPOSITION METHOD

(71) Applicant: Masahiro Yamamoto, Osaka (JP)

(72) Inventor: Masahiro Yamamoto, Osaka (JP)

(21) Appl. No.: 14/007,681

(22) PCT Filed: Feb. 15, 2012
(86) PCT No.: PCT/JP2012/000989

§ 371 Date: Sep. 26, 2013

(30) Foreign Application Priority Data
Mar. 29, 2011 (JP) 2011-073208

(51) Int. Cl. C23C 14/34

(52) U.S. Cl. CPC C23C 14/34
USPC 204/192.1; 204/298.11

(57) ABSTRACT

A deposition apparatus comprises a vacuum chamber; a substrate holder; a target; and an angle correcting plate provided so as to cover an upper space of the principal surface of the substrate, and provided outside a spatial region encompassed by line segments connecting a periphery of the principal surface of the target and a periphery of the principal surface of the substrate, wherein when an arbitrary point on the principal surface of the substrate is denoted by B and at least a center point on the principal surface of the target is denoted by C, a part of the principal surface of the angle correcting plate exists on each line which forms 45° from the respective point B with respect to each line which connects the respective point B and the point C, and another part of the principal surface of the angle correcting plate extends to a side opposite to the target.

### CROSS-REFERENCE TO RELATED APPLICATIONS

This application is a U.S. national phase application of PCT International Patent Application No. PCT/JP2012/000989 filed Feb. 15, 2012, claiming the benefit of priority of Japanese Patent Application No. 2011-073208 filed Mar. 29, 2011, all of which are incorporated by reference herein in their entirety.

### FIELD OF THE INVENTION

The present invention relates to a deposition method of a thin film and a deposition apparatus, and especially relates to a deposition method and a deposition apparatus which control an incident angle of the incident material particle to a substrate.

### BACKGROUND OF THE INVENTION

There are a vacuum deposition method, a sputtering method, a CVD method and the like as technology which forms a thin film. These deposition methods are important technology for realizing recent high-function devices such as semiconductors, because a characteristic different from that of a bulk material can be acquired by forming the thin film. One of them is technology which controls the angle of material particles incident to a substrate to perform anisotropic growth.

In the case of the vacuum deposition method, the sputtering method and the like, a substrate and an evaporation source are disposed at a distance to make evaporation particles, which have the comparatively equal incidence directions, be deposited on the substrate. It is known that, if the substrate is tilted and located at this time rather than arranged so that it may become perpendicular to the incidence direction of evaporation particles, the growth of the film progresses in the slant direction.

Such an aslant grown-up film indicates the physical properties which differ from that of the bulk material, and for example, is applied to a high-density magnetic-recording medium and the like. Moreover, when the deposition is performed while changing the incident angle of the material particle, it is possible to form a three-dimensional structure of a nanometer order, and application to a MEMS (Micro Electro Mechanical Systems) device and the like are considered.

Ideally, in order to make the film grow up in accordance with an aim, it is desirable to obtain, by controlling an angle distribution of incident particles, the material particles of a single angle.

On the other hand, the particles emitted from the evaporation source have the angle distribution. In the case of either a crucible of the vacuum deposition or a target of the sputtering method, it is said that the angle of an emitted evaporation particle can be typically approximated with a distribution shape approximating to a cosine law in which, when the angle from a perpendicular direction is set to θ, the evaporation particle flux emitted in the direction of θ is proportional to the exponentiation of Cos θ.

There is a way to separate the substrate from the evaporation source as one way of thinking for bringing the angle distribution of the evaporation particles incident to a substrate close to a single angle. Since the expected angle of the evaporation source viewed from the substrate becomes small, the longer the distance becomes, the narrower the incident angle distribution becomes.

However, if the distance between the evaporation source and the substrate becomes long, a possibility that the evaporation particles collide with residual gas becomes high while moving in the space between them, and the degree to which a direction of movement changes becomes high. Therefore, the incident angle distribution to the substrate becomes wider. In general, by raising ability for exhaust to remove the residual gas, the designing is performed to keep going straight characteristics of the evaporation particle, but a vacuum pump becomes large and the price of facilities also rises.

On the other hand, there is also a way of thinking to install a structure between the evaporation source and the substrate so that the particles, which jumped out at the inappropriate angle from the evaporation source, among the evaporation particles are cut on the way. This is, for example, a method in which a collimator shown in the patent document whose Publication Number about Japanese translation of PCT international application is 2005-530919 is used.

According to this method, the incident angle distribution of the evaporation particles can be narrowed, but installation of a collimator between the evaporation source and the substrate lowers the quantity of the evaporation particles which reach to a substrate. Moreover, an effect is reduced when suffering dispersion due to the residual gas after passing the collimator. Therefore, a sufficient effect was not able to be acquired when the deposition was performed by introducing reactant gas positively, or when it was hard to avoid the gas release from a chamber wall in a large-sized apparatus and the like.

Further, unlike the above-mentioned constitution, there is also technology of installing a shield plate so that the shield plate may not invade between the evaporation source and the substrate, so as to prevent the evaporation particles from attaching to the unnecessary region such as an inner wall of the chamber (for example, Japanese Patent Laid-open Number 2003-13206). For example, in the patent document whose Japanese Patent Laid-open Number is 2003-13206, it is also disclosed to make the position variable so that the position may not become the hindrance of deposition.

### SUMMARY OF THE INVENTION

### Problems to be Solved by the Invention

However, the inventor of the present invention carried out the slanting deposition to projections by the vacuum deposition method (refer to FIG. 3) base on the conventional technology described above, and found out that, especially in the case where reactant gas was introduced, the incident angle of the evaporation particle was not able to be sufficiently realized. The schematic view of the substrate 6 having projections and the situation of the film attaching thereto are shown in FIG. 2(a) and FIG. 2(b).

That is to say, as shown in FIG. 2(a), in order to prevent attachment of the film 18 to a bottom part between the projections, the inventor of the present invention tried to supply the evaporation particles 17 aslant. However, the film 18 that was actually deposited had adhered also to the bottom part as shown in FIG. 2(b), and the result, which suggests that many evaporation particles 17 are flying over also from the perpendicular direction of the substrate, was obtained.

Here, the conventional example of the deposition apparatus is shown in FIG. 3, which supplies the evaporation particles aslant to the substrate.

As shown in FIG. 3, the numeral 1 denotes a vacuum chamber, the numeral 2 denotes a target, the numeral 3 denotes a backing plate and the numeral 4 denotes a high-voltage impression power supply. A substrate holder 5 is located at a position such that it faces to the target 2, and is provided with a substrate 6 as an object to be processed. The numeral 7 denotes an exhaust apparatus, the numeral 8 denotes an exhaust port, the numeral 9 denotes a valve, the numeral 10 denotes a ground shield and the numeral 11 denotes a magnetic circuit.

At this time, in the conventional deposition apparatus, the distance between the substrate 6 and the evaporation source 2 was 590 mm, and the pressure during the deposition process was 0.1 Pa. Here, as reference of the frequency with which the evaporation particles collide with reactant gas, a theory of the mean free path between the oxygen gases was applied by using oxygen as one example.

In that case, the length of the mean free path was 106 mm at 300K and 0.1 Pa, and in the distance to the substrate, the evaporation particles collide around six times on the average. It is thought that, for this reason, the incident angle distribution becomes wider and the desired film which is deposited aslant was not completed.

By the way, a collision of the evaporation particle and oxygen gas differs from a collision between the oxygen, but can be used as reference for evaluating a dispersion degree.

An aspect of the present invention provides a deposition apparatus and a deposition method which suppress the evaporation particles incident to a substrate at an inappropriate angle and can realize a deposition with the evaporation particles of the desired incident angle.

### SUMMARY OF THE INVENTION

The 1^{st} aspect of the present invention is a deposition apparatus comprising:

a vacuum chamber;

a holding part which holds a base member in the vacuum chamber;

an evaporation source which has a principal surface inclined with respect to a principal surface of the base member which is held, and holds a deposition material; and

an angle correcting member which is provided so as to cover an upper space of the principal surface of the base member, and is provided outside a spatial region which is encompassed by line segments which connect a periphery of the principal surface of the evaporation source and a periphery of the principal surface of the base member, wherein

the principal surface of the base member, the principal surface of the evaporation source and a principal surface facing the base member, of the angle correcting member, extend to a depth direction in a case of viewing from a front of the vacuum chamber,

when an arbitrary point on the principal surface of the base member is denoted by a first point and at least a center point on the principal surface of the evaporation source is denoted by a second point in a case of viewing from the front of the vacuum chamber,

at least a part of the principal surface of the angle correcting member exists on each line which forms 45° from the respective first points with respect to each line which connects the respective first points and the second point, and another part of the principal surface of the angle correcting member extends to a side opposite to the evaporation source.

By means of this, it is possible to control the incident angle of the evaporation particles effectively, reduced the evaporation particles incident to a substrate at an inappropriate angle, and realize a deposition with the evaporation particles of the desired incident angle.

The 2^{nd} aspect of the present invention is the deposition apparatus according to the 1^{st} aspect of the present invention, wherein

at least the part of the principal surface of the angle correcting member exists at a position of a mean free path of water molecules or less away from the respective first points.

By means of this, it is possible to control the incident angle of the evaporation particles more effectively, reduce the evaporation particles incident to a substrate at an inappropriate angle, and realize a deposition with the evaporation particles of the desired incident angle.

The 3^{rd} aspect of the present invention is the deposition apparatus according to the 2^{nd} aspect of the present invention, wherein

the other part of the principal surface of the angle correcting member exists on each line which forms a second angle which is more than 45°, from the respective first points, to each line which connects the respective first points and the second point, exists at a position of a second distance which is more than the mean free path of water molecules away from the respective first points, and a relation formula, which is {(45°/(the second angle)}×(the second distance)≦the mean free path, is established.

By means of this, regarding the first point on the substrate, where the second angle becomes larger than 45°, it is possible to set up the above-mentioned second distance larger than the length of the mean free pass, and the flexibility of the shape of the angle correcting member improves, because the influence of the particles flying over is small.

The 4^{th} aspect of the present invention is the deposition apparatus according to any one of the 1^{st} to 3^{rd} aspects of the present inventions, wherein

the angle correcting member is constituted by a plurality of members provided with holes or a plurality of members provided with meshes or slits.

By means of this, since gas can be prevented from stagnating in a space which is sandwiched between the angle correcting member and the substrate and maintaining at a high vacuum is possible, it is possible to reduced the evaporation particles incident to a substrate at an inappropriate angle and realize a deposition with the evaporation particles of the desired incident angle.

The 5^{th} aspect of the present invention is the deposition apparatus according to any one of the 1^{st} to 4^{th} aspects of the present inventions, wherein

the angle correcting member is provided with a cooling mechanism.

By means of this, since degassing from the angle correcting member can be reduced and detachment of the evaporation particles which attached to the angle correcting member can be prevented, it is possible to reduced the evaporation particles incident to a substrate at an inappropriate angle and realize a deposition with the evaporation particles of the desired incident angle.

The 6^{th} aspect of the present invention is the deposition apparatus according any one of to the 1^{st} to 5^{th} aspects of the present inventions, wherein

the angle correcting member is movable with respect to the base member during deposition.

By means of this, it is possible to reduced the evaporation particles incident to a substrate at an inappropriate angle and realize a deposition with the evaporation particles of the desired incident angle.

The 7^{th} aspect of the present invention is a deposition method for a deposition apparatus which comprises a vacuum chamber, a holding part which holds a base member in the vacuum chamber, an evaporation source which has a principal surface inclined with respect to a principal surface of the base member which is held, and holds a deposition material, and an angle correcting member which is provided so as to cover an upper space of the principal surface of the base member, and is provided outside a spatial region which is encompassed by line segments which connect a periphery of the principal surface of the evaporation source and a periphery of the principal surface of the base member, wherein

the principal surface of the base member, the principal surface of the evaporation source and a principal surface facing the base member, of the angle correcting member, extend to a depth direction in a case of viewing from a front of the vacuum chamber,

when an arbitrary point on the principal surface of the base member is denoted by a first point and at least a center point on the principal surface of the evaporation source is denoted by a second point in a case of viewing from the front of the vacuum chamber,

regulating a direction from which the deposition material flies over with respect to the base member by using the angle correcting member in which at least a part of the principal surface of the angle correcting member exists on each line which forms 45° from the respective first points with respect to each line which connects the respective first points and the second point, and another part of the principal surface of the angle correcting member extends to a side opposite to the evaporation source.

By means of this, it is possible to control the incident angle of the evaporation particles effectively, reduced the evaporation particles incident to a substrate at an inappropriate angle, and realize a deposition with the evaporation particles of the desired incident angle.

The 8^{th} aspect of the present invention is the deposition method according to the 7^{th} aspect of the present invention, wherein

at least the part of the principal surface of the angle correcting member exists at a position of a mean free path of gas or less, which is introduced in the vacuum chamber, or a mean free path of water molecules or less, which exist in the vacuum chamber, away from the respective first points.

By means of this, it is possible to control the incident angle of the evaporation particles more effectively, reduce the evaporation particles incident to a substrate at an inappropriate angle, and realize a deposition with the evaporation particles of the desired incident angle.

The 9^{th} aspect of the present invention is the deposition method according to the 8^{th} aspect of the present invention, wherein

the other part of the principal surface of the angle correcting member exists on each line which forms a second angle which is more than 45°, from the respective first points, to each line which connects the respective first points and the second point, exists at a position of a second distance which is than the mean free path of water molecules away from the respective first points, and a relation formula, which is {(45°/(the second angle)}×(the second distance)≦the mean free path, is established.

By means of this, regarding the first point on the substrate, where the second angle becomes larger than 45°, it is possible to set up the above-mentioned second distance larger than the length of the mean free pass, and the flexibility of the shape of the angle correcting member improves, because the influence of the particles flying over is small.

The 10^{th} aspect of the present invention is the deposition method according to any one of the 7^{th} to 9^{th} aspects of the present inventions, wherein

the angle correcting member is constituted by a plurality of members provided with holes or a plurality of members provided with meshes or slits.

By means of this, since gas can be prevented from stagnating in a space which is sandwiched between the angle correcting member and the substrate and maintaining at a high vacuum is possible, it is possible to reduced the evaporation particles incident to a substrate at an inappropriate angle and realize a deposition with the evaporation particles of the desired incident angle.

The 11^{th} aspect of the present invention is the deposition method according to any one of the 7^{th} to 10^{th} aspects of the present inventions, wherein

the angle correcting member is provided with a cooling mechanism, and

performing deposition while cooling a temperature of the angle correcting member.

By means of this, since degassing from the angle correcting member can be reduced and detachment of the evaporation particles which attached to the angle correcting member can be prevented, it is possible to reduced the evaporation particles incident to a substrate at an inappropriate angle and realize a deposition with the evaporation particles of the desired incident angle.

The 12^{th} aspect of the present invention is the deposition method according to any one of the 7^{th} to 11^{th} aspects of the present inventions, wherein

the angle correcting member is movable with respect to the base member during deposition, and

performing deposition while changing an incident angle distribution of an evaporation particle to the base member by moving a position of the angle correcting member to a different position and performing deposition at the respective positions.

By means of this, it is possible to control the incident angle of the evaporation particles effectively, reduce the evaporation particles incident to a substrate at an inappropriate angle, and realize a deposition with the evaporation particles of the desired incident angle.

### Advantageous Effects of the Invention

As described above, according to a deposition apparatus and a deposition method using an angle correcting member of the present invention, it is possible to suppress the evaporation particles incident to a substrate at an inappropriate angle and realize a deposition with the evaporation particles of the desired incident angle.

### BRIEF DESCRIPTION OF THE DRAWINGS

FIG. 1 is a schematic front view of a deposition apparatus according to Embodiment 1 of the present invention;

FIGS. 2(a) and 2(b) are schematic front views illustrating, in a case of the slanting deposition to the substrate having projections, an example of the situation of the film attaching thereto by using a conventional vacuum deposition method;

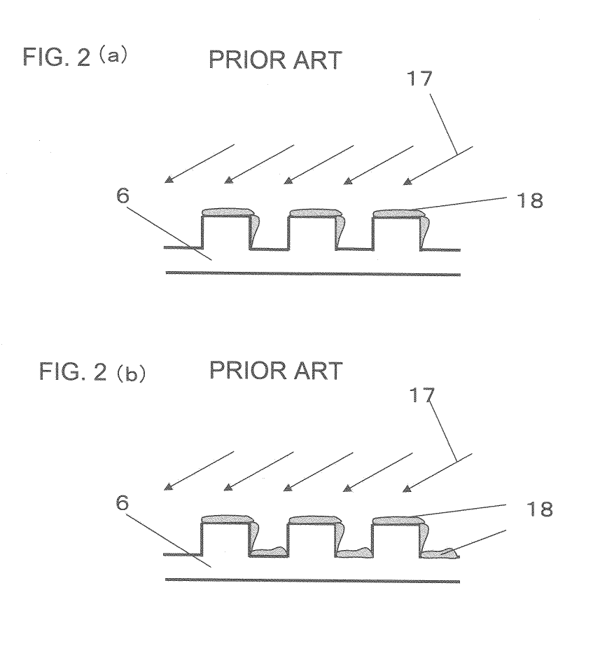

FIG. 3 is a schematic front view illustrating an example of a conventional deposition apparatus;

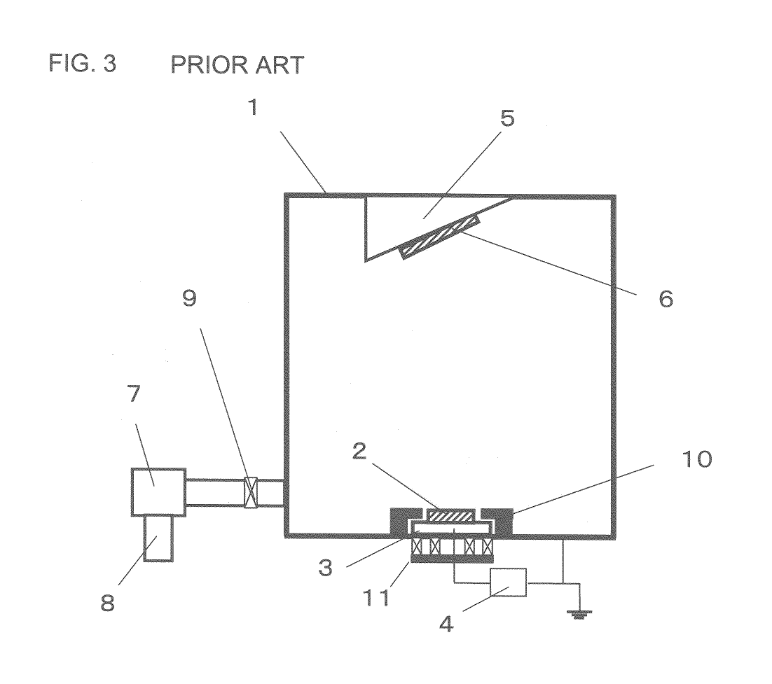

FIG. 4 is a view explaining a conventional anticipation about the situation where incident angle distribution of evaporation particles changes by the internal pressure of the chamber;

FIG. 5 is a schematic front view of a model which is used in a simulation performed in order to obtain the incident angle distribution of the evaporation particles according to the present Embodiment 1;

FIG. 6 is a view illustrating the result of having carried out the simulation of the change of incident angle distribution of the evaporation particles by the difference in the pressure in a vacuum chamber according to the present Embodiment 1;

FIG. 7 is a schematic front view illustrating a modified example of the angle correcting plate according to the present Embodiment 1;

FIG. 8 is a schematic front view of a deposition apparatus as a modified example of the Embodiment 1 of the present invention;

FIG. 9 is a schematic view illustrating a constitution example of an angle correcting plate which is constituted by a plurality of correcting members according to the Embodiment 2 of the present invention;

FIG. 10 is a schematic front view illustrating a constitution example of a deposition apparatus which is provided with a cooling mechanism according to the present Embodiment 3 of the present invention; and

FIGS. 11(a) to 11(d) are schematic views illustrating an example of deposition method according to the present Embodiment 4.

### MODES FOR CARRYING OUT INVENTION

In the following, an embodiment of the present invention will be described, referring to drawings.

### Embodiment 1

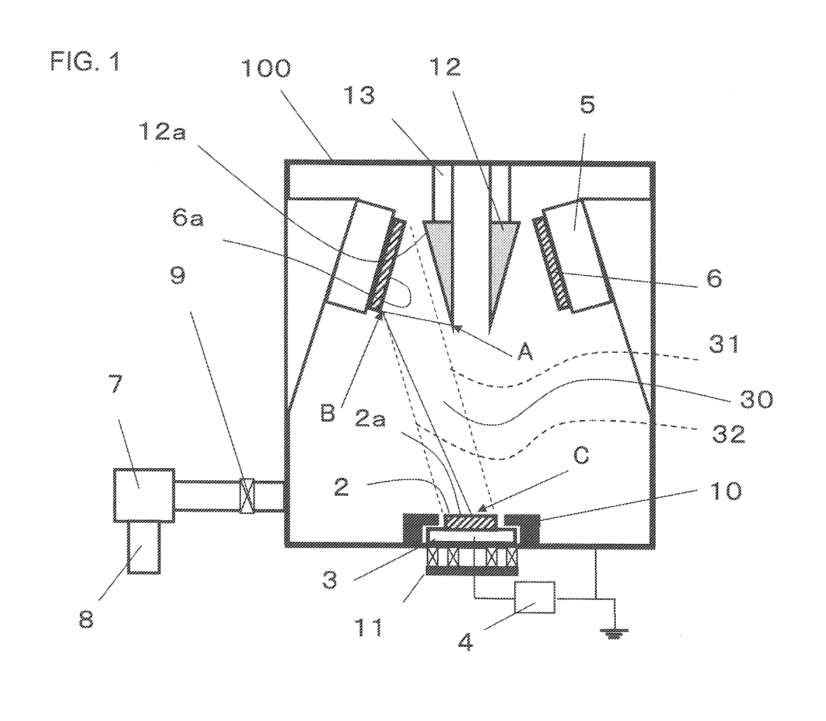

FIG. 1 is a schematic front view of a deposition apparatus according to Embodiment 1 of the present invention. In the embodiment of the present invention, the numeral 100 denotes a vacuum chamber, the numeral 2 denotes a target, the numeral 3 denotes a backing plate and the numeral 4 denotes a high-voltage impression power supply. The power supply may be a direct-current power supply, a high-frequency power supply, a pulse power supply, or these superposition. A substrate holder 5 is located at a position such that it faces to the target 2, and is provided with a substrate 6 as an object to be processed. The numeral 7 denotes an exhaust apparatus, the numeral 8 denotes an exhaust port, the numeral 9 denotes a valve, the numeral 10 denotes a ground shield and the numeral 11 denotes a magnetic circuit. Further, an angle correcting plate 12 is disposed in front of the substrate 6 and is held by a movement mechanism in such a manner that the angle correcting plate 12 can be moved.

The angle correcting plate 12 is, as shown in FIG. 1, provided outside a spatial region 30 which is encompassed by a first line segment 31, which connects an arbitrary point on the upper end part of the periphery of the principal surface 6a of the substrate 6 and an arbitrary point on the right end part of the periphery of the principal surface 2a of the target 2, a second line segment 32, which connects an arbitrary point on the lower end part of the periphery of the principal surface 6a of the substrate 6 and an arbitrary point on the left end part of the periphery of the principal surface 2a of the target 2, a third line segment (not shown), which connects an arbitrary point in the end part on the nearer side in FIG. 1 of the periphery of the principal surface 6a of the substrate 6 and an arbitrary point in the end part on the nearer side in FIG. 1 of the periphery of the principal surface 2a of the target 2, and a fourth line segment (not shown), which connects an arbitrary point in the end part on the farther side in FIG. 1 of the periphery of the principal surface 6a of the substrate 6 and an arbitrary point in the end part on the farther side of the periphery of the principal surface 2a of the target 2.

Here, each surface of the principal surface 6a of the substrate 6, the principal surface 2a of the target 2 and the principal surface 12a on a side of the angle correcting plate 12, the side facing the substrate 6, extends to the farther side direction in the figure on the front of the vacuum chamber 100 shown in FIG. 1.

Incidentally, one example of a holding part of the present invention corresponds to the substrate holder 5 of the present embodiment, one example of a base member of the present invention corresponds to the substrate 6 of the present embodiment, one example of an evaporation source of the present invention corresponds to the target 2 of the present embodiment. Moreover, one example of a spatial region of the present invention corresponds to the spatial region 30 of the present embodiment.

By the way, generally, when performing evaporation in the vacuum chamber, since the evaporation particle, which is dispersed by the residual gas between the evaporation source and the substrate, changes a direction of movement, the actual incident angle of the evaporation particle to the substrate changes.

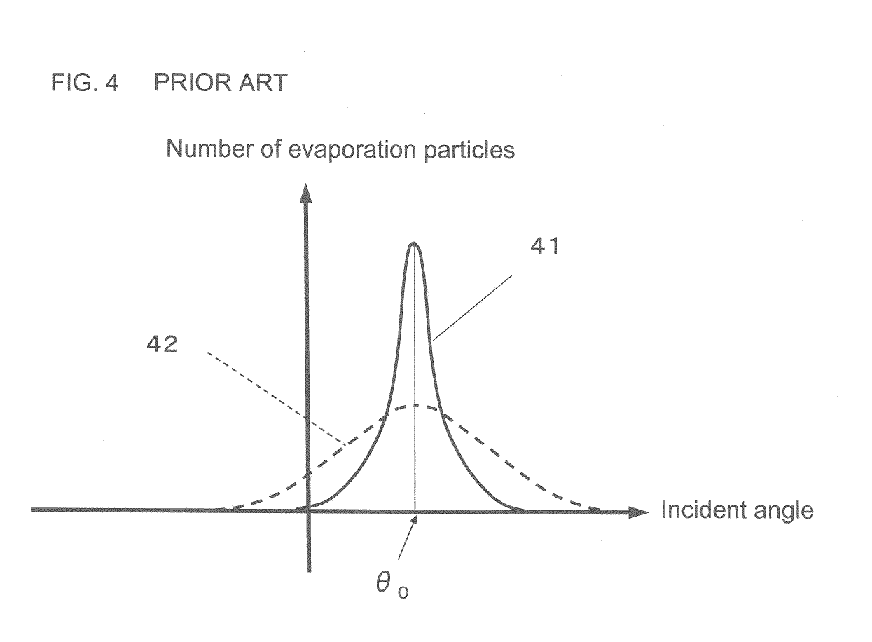

FIG. 4 shows a conception diagram, based on the conventional usual prediction, of the change of distribution of the incident angle of the evaporation particles resulting from the difference in a degree of vacuum in the vacuum chamber. According to the conventional prediction, when a vacuum degree changed from a high state (refer to a first distribution curve 41 of FIG. 4) to a low state (refer to a second distribution curve 42 of FIG. 4), and it was expected that the phenomenon arises, in which the central location of the distribution of the incident angle of the evaporation particles did not change and the distribution widths of the respective distribution curves widen.

Specifically, the first distribution curve 41 of FIG. 4 shows that since there is few the dispersion of the evaporation particle in a case where the degree of vacuum is high (for example, 0.01 Pa), the width of the variation in the incident angle, where a central angle θ₀ of the distribution is allowed to be centered, becomes narrow. Moreover, the second distribution curve 42 shows that since the dispersion of the evaporation particle increases in a case where the degree of vacuum is low (for example, 0.1 Pa), the width of the variation in the incident angle, where a central angle θ₀ of the distribution is allowed to be centered, becomes wider.

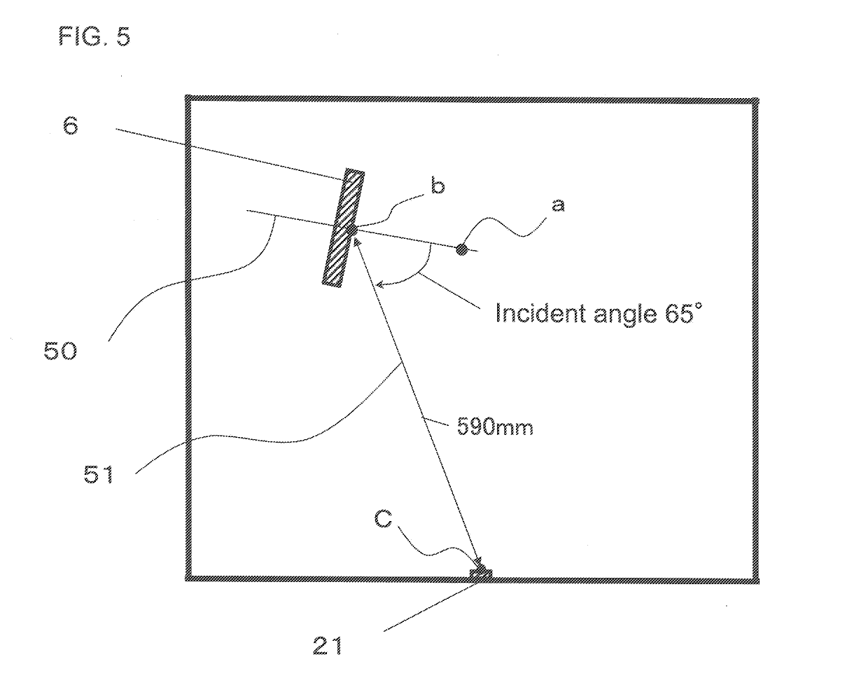

Incidentally, the incident angle on the horizontal axis of FIG. 4 is, like the case of FIG. 5 that will be described below, the angle between the normal line of the substrate, which is to serve as reference, and the incidence direction of the evaporation particle.

However, according to the experiment of the inventor of the present invention, when deposition was performed by holding the substrate being tilted by approximately 70° and located approximately 600 mm away from the evaporation source, with Ar used as the residual gas and the inside pressure of the vacuum chamber set at approximately 0.1 Pa, as a result of observing the film attaching to the bottoms of holes, which were located on the substrate surface with approximately 10 μm pitch and aspect of around 1.0, acquired was the knowledge that many particles entering from a normal direction of the substrate surface also exist.

Here, the inclination angle (approximately 70°) of the substrate means the angle between the normal line (refer to a normal line 50 of FIG. 5, which will be described below) at the center of the substrate surface, which is to serve as reference, and a virtual line (refer to a line segment 51 of FIG. 5, which will be described below) which connects the center of the substrate surface and the center of the evaporation source.

Thus, the inventor of the present invention thought that it was necessary to investigate in detail the incident angle distribution of the evaporation particles which enter into the substrate, and performed a simulation based on a Direct Simulation Monte Carle (DSMC) method in order to analyze a flow of dilute fluid.

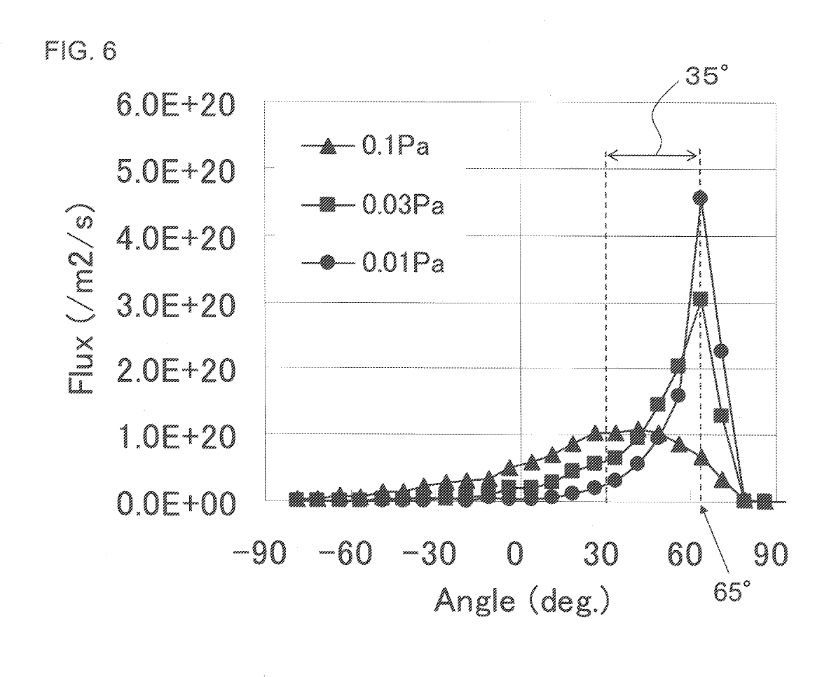

In the following, this simulation will be described whit reference to FIG. 5 and FIG. 6.

In FIG. 5, a schematic front view of a model of the vacuum chamber which is used in this simulation is shown. The model was allowed to be of simple form, the distance between the evaporation source 21 and the substrate 6 was allowed to be 590 mm by supposing a vacuum deposition, and the incident angles of the evaporation particles at a center point b on the plane of the facing substrate 6 were acquired.

The evaporation material was allowed to be Si, the residual gas was allowed to be He, the pressure in the vacuum chamber was allowed to be 0.01, 0.03 and 0.1 Pa. A geometric incident angle ∠abc was allowed to be 65°.

This geometric incident angle ∠abc is defined as the angle between the normal line 50 at the center point b of the substrate 6 in FIG. 5, which is to serve as reference, and the line segment 51 which connects the center point b and the center point c of the surface of the evaporation source 21.

Moreover, in this simulation, the incident angle of the evaporation particle, which is dispersed by the residual gas between the evaporation source 21 and the substrate 6 and flies over, is defined with reference to the above-mentioned normal line 50. For example, as shown in FIG. 5, the incident angle in a case, where the evaporation particle enters into from ab-direction (normal direction) as shown in FIG. 5, can be denoted 0°.

Incidentally, here, point a is a point which is located on the normal line 50 of the substrate 6.

The results of the simulation of FIG. 5 is shown in FIG. 6. That is to say, FIG. 6 shows a change of the incident angle distribution of the evaporation particles by the difference in pressure (degree of vacuum) in the vacuum chamber.

According to FIG. 6, unlike the phenomenon shown in FIG. 4 that was predicted conventionally, it is understood that in the case where the pressure in the vacuum chamber is higher (the degree of vacuum is low), the peak position of the incident angle distribution is shifted to the direction which is near to the vertical incidence (the position on the horizontal axis of FIG. 6 where the angle becomes 0°) compared with the case where the pressure is lower (the degree of vacuum is high). Here, the horizontal axis of FIG. 6 denotes the angle between the normal line 50 shown in FIG. 5, with the normal line 50 being reference, and the incidence direction of the evaporation particle.

That is to say, in FIG. 6, in the case where the pressure in the vacuum chamber is 0.01 Pa, the peak of the incident angle distribution is near to 65°, but, in the case where the pressure in the vacuum chamber is 0.1 Pa, the peak of the incident angle distribution is shifted to the neighborhood of 30°.

That is to say, according to the result of the above-mentioned simulation, in the situation where dispersion occurs in a certain probability or more (the situation where the degree of vacuum is low), the ratio of the evaporation particles that seemingly enter from the direction opposite to the deposition source 21 viewed from the substrate 6 (for example, the evaporation particles which are plotted in the region where the value on the horizontal axis of FIG. 6 is in the neighborhood of 0, and in the region which shows minus values) increases.

It seems to be hard to understand such a result at first glance because it is different from the conventional usual prediction, but the reason is that the ratio of the evaporation particles increases, which suffer dispersion in the upper space of the substrate 6, change the direction of movement and enter to the substrate. It means that when the pressure in the vacuum chamber is continuously raised (when the degree of vacuum is continuously lowered), the ratio of the evaporation particles which perpendicularly enter to the substrate 6 (the evaporation particles which are plotted in the region where the value on the horizontal axis of FIG. 6 is 0) increases, and that the relation between the position of the evaporation source 21 viewed from the substrate 6 and the incident angle of the evaporation particle is lost.

Although He of the residual gas was replaced with oxygen, and the same simulation as the above was performed, the same tendency was acquired. In the case where oxygen as the residual gas was used, since the molecular weight of oxygen was large compared with He, the pressure in the vacuum chamber is one half of the pressure in the case of He, and the almost equivalent dispersion state was acquired. That is to say, the dispersion state where the residual gas was He and the pressure in the vacuum chamber was 0.1 Pa was equal to the dispersion state where the residual gas was oxygen and the pressure was one half of the pressure, that is to say, 0.05 Pa.

The inventor of the present invention, based on the above-mentioned results, found out that, in order to keep the incident angle of the particles with respect to the substrate 6 within a desirable range, it is important not to provide a space above the substrate 6 as described above, in the direction opposite to the evaporation source 21 viewed from the substrate 6, where the evaporation particles suffer dispersion.

Thus, as shown in FIG. 1, an angle correcting plate 12 was disposed in order that a space above the substrate 6 is not allowed to exist in the direction opposite to the evaporation source 21 viewed from the substrate 6, where the evaporation particles suffer dispersion.

In the following, by returning to FIG. 1 again, the angle correcting plate 12 of the present embodiment will be described.

The position of the angle correcting plate 12 is adjusted so that the angle correcting plate 12 does not exist on the straight line which connects an arbitrary evaporation point C on the target 2 and an arbitrary point B on the substrate 6. At this point, the present invention is different from the invention (for example, Publication Number about Japanese translation of PCT international application: 2005-530919 and the like) which has a concept in which a correcting plate is installed between the target and the substrate. By the way, one example of an angle correcting member of the present invention according to the angle correcting plate 12 of the present embodiment. One example of a first point of the present invention according to the point B of the present embodiment and one example of a second point of the present invention according to the point C of the present embodiment.

In the principal plane 12a of the angle correcting plate 12, the size including the degree and the like of the projection of the tip side (a portion of the side which is nearer to the target 2) is determined so that, when a point on the angle correcting plate 12 is denoted by A, a point A, which makes the angle ∠ABC become 45° with respect to an arbitrary point B, exists.

Here, ∠ABC=45° is, with reference to each line (hereinafter, this line is referred to as a BC line) which connects an arbitrary evaporation point C and an arbitrary point B on the substrate 6, the angle between the line which connects the arbitrary point B and the point A, and the BC line. Moreover, ∠ABC=45° is the angle determined by experiment, taking into consideration the simulation result, which has been described with FIG. 6, in a case where the residual gas exists in the vacuum chamber and the degree of vacuum is low (when the pressure of the vacuum chamber is 0.1 Pa, there is a peak of the incident angle distribution in the neighborhood of 30° with reference to the normal line 50). This matter will be further described later.

That is to say, if the setting ∠ABC=45° is done with respect to the arbitrary point B and point C, exerted is an effect such that, even if there is variation in the incident angle of the evaporation particle, the evaporation particle, which enters from the inclination direction, at an angle in the limited range, can be made to attach to the substrate 6.

By the way, the geometric incident angle ∠abc is defined as an angle between the normal line which is to serve as reference and the line segment 51, but, angle ∠ABC shown in FIG. 1 is defined as an angle between the line segment BC which is to serve as reference and the line segment AB in order to make an understanding of the following explanation easy.

Meanwhile, in order to regulate the angle, at which the evaporation particle flies over, so that it is in the predetermined range, the smaller the angle ∠ABC determining the size of the tip side of the principle surface 12a of the angle correcting plate 12 is, the greater the advantage is. However, if this angle ∠ABC is allowed to be too small, that is to say, if the tip portion (refer to the position of the point A shown in FIG. 1) of the principle surface 12a of the angle correcting plate 12 is allowed to be lengthened too much in the direction of the target 2, most of the evaporation particles supplied from the target 2 cannot reach the substrate 6, and the deposition efficiency decreases.

On the other hand, the angle ∠ABC, which was defined with reference to the line segment BC, can be regarded as a shift angle to the incident angle of an aim (here, the incidence angle of the aim is 0° with reference to the line segment BC). That is to say, the evaporation particles, which enter in the direction from A toward B, are prevented with the angle correcting plate 12. It is thought that such evaporation particles, which enter in the direction from A toward B, are particles which result from changing of the direction of movement due to the collision with the residual gas on the way of the movement, and that the existence probability thereof decreases as the above-mentioned shift angle (angle ∠ABC) with reference to the line segment BC becomes large.

As a result of the inventor of the present invention doing a zealous examination from the above-mentioned viewpoint, if the angle correcting plate 12 is installed in the position which fulfills the condition about the above-mentioned angle ∠ABC and moreover the distance between A and B is equal to a mean free path L of the introduced gas or less, it was found out that the angle distribution was controllable better.

In the following, the condition about the above-mentioned angle ∠ABC and the condition about the distance between A and B will be mainly described.

As shown in FIG. 6, in a case where the pressure of the vacuum chamber is 0.1 Pa, the peak is shifted to about 30° (which has the shift of 35° from the incident angle 65° that is the angle of the aim) with respect to the set 65° as an aim incident angle ∠abc with reference to the normal line 50 (refer to FIG. 5).

The foregoing indicates that, since an incident angle component which has a larger difference with respect to the angle of the aim has greater influence, it is necessary to pay attention to the incident angle component of 30° or less in particular.

However, according to the above-mentioned reason, if the angle ∠ABC is too small, the deposition efficiency decreases and it is not desirable.

The experiment performed in consideration of the above-mentioned condition confirms that, actually, by setting the angle ∠ABC to 45°, as the condition for the above-mentioned angle ∠ABC, it is possible to reduce on a satisfactory level the rate such that the evaporation particles, which are distributed in the directions from the neighborhood of 30° to 0° with reference to the normal line on the horizontal-axis shown in FIG. 6 (corresponding to the incidence direction of the evaporation particle which enters perpendicularly from the portion above the substrate 6), enter into the substrate surface.

Moreover, regarding the distance between A and B, when with respect to the typical metal evaporation particle whose atomic weight is around 60, the case, where oxygen gas is introduced and it is collision between the hard spheres, is assumed, it is understood that a change of the angle which occurs in one collision becomes about 20° to 30° on the average from the calculation, which takes an impact parameter into consideration, of an easy collision of the hard sphere.

An evaporation particle, which suffers from collisions two or more times, very rarely changes the angle in the same direction successively, and the quantity of the angle shift cannot be estimated simply by the multiplication of the average angle change and the mean collision frequency. However, if the distance between A and B becomes equal to the mean free path L or more, the angle changes are accumulated by a plurality of collisions of the evaporation particle, so it is possible to presume that decreases the effect of removing the components with large angle changes by setting the angle ∠ABC to 45° by the angle correcting plate 12.

By means of this, it is desirable that the distance between A and B be kept equal to the mean free path L or less.

On the other hand, for the good angle distribution, it is desirable that the distance between the substrate 6 and the angle correcting plate 12 be smaller but, if the distance is too small, the probability of the arrival of the evaporation particles to the substrate 6 decreases, so it is also not desirable that the distance be set unnecessarily too narrow.

By installing the angle correcting plate 12 which fulfills the above-mentioned conditions (the condition about the angle ∠ABC and the condition about the distance between A and B), the undesirable components of the evaporation particles, which enter from the direction opposite to the target 2 viewed from the substrate 6, can be reduced, and from a result of the simulation, it has become possible to remove the components with a shift of 35° or more from the angle of the aim (the incident angle of the aim is 65° in FIG. 6).

Incidentally, even if the angle correcting plate 12 is of constitution which fulfills only the condition about the angle ∠ABC=45° between the above-mentioned two conditions, for example, in a case where the degree of vacuum in the vacuum chamber is high, exerted is an effect such that the evaporation particles, which enter into the substrate at an inappropriate angle, are suppressed, and the deposition by the evaporation particles of the desired incident angle can be realized.

Next, the condition about the distance between A and B will be further described.

That is to say, more effectively, the distance between A and B should be determined with correlation with angle ∠ABC.

This is because the distribution of the components which have the large quantity shifted from the incident angle of the aim tends to decrease while going to the direction of 0°.

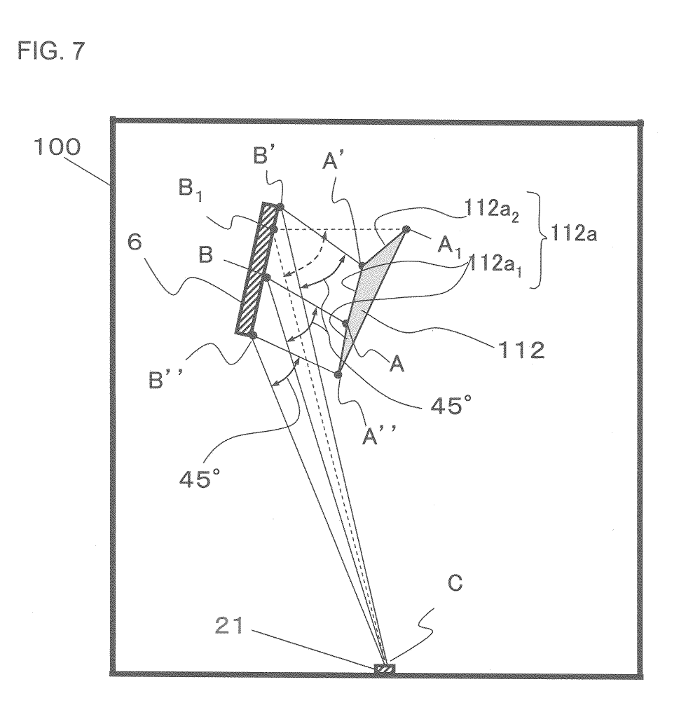

Specifically, as shown in FIG. 7, regarding a position B₁ on the substrate 6, where the angle ∠A₁B₁C becomes larger than 45° with reference to the line segment B₁C, since the incident angle of the evaporation particle, which flies over from the position A₁ to the position B₁, approaches the neighborhood of 0° with reference to the normal line of the substrate 6, the influence of the evaporation particles flying over becomes small as shown in FIG. 6.

Therefore, the shape of the angle correcting plate may be determined by setting up the distance between A₁ and B₁ larger than the mean free path L of the introduced gas. But, it is necessary to satisfy the relation formula (I) which will be mentioned later.

Here, FIG. 7 is a schematic view for explaining a second angle correcting plate 112 as a modified example of the angle correcting plate 12 shown in FIG. 1. In FIG. 7, only constitution necessary for understanding the explanation of the second angle correcting plate 112 is shown, and as for the constitution except that (for example, substrate holder 5, exhaust apparatus 7, moving mechanism 13 and the like), the illustration thereof is omitted, and the basic constitution is the same as that in FIG. 1.

More specifically, as shown in FIG. 7, the angles satisfy ∠ABC=∠A′B′C=∠A″B″C=45, which are determined by points A, A′ and A″ on a principle surface 112a₁ of the tip side (a portion of the side which is nearer to the evaporation source 21) of the principle surface 112a of the second angle correcting plate 112, respective points B, B′ and B″ which are on the substrate 6 and correspond to them, and the center point C on the evaporation source 21. Moreover, all of the lengths of a line segment AB, a line segment A′B′, and a line segment A″B″ are equal to or less than L. Further, in FIG. 7, an example of constitution which determines the shape of a principle surface 112a₂ of the other part is shown by setting the length of a line segment A₁B₁ larger than L, under a condition such that the relation formula (1) below is satisfied, because ∠A₁B₁C>45°, which is determined by a point A₁ on the principle surface 112a₂ of the other part (a portion which extends to the opposite side of the evaporation source 21) of the principle surface 112a of the second angle correcting plate 112, a point B₁ which is on the substrate 6 and corresponds to it, and the point C.

Thus, when a center point on the evaporation source 21 is denoted by C, an arbitrary point on the substrate 6 is denoted by B, and a point, which is on the principle surface 112a₂ of the other part (a portion which extends to the opposite side of the evaporation source 21) of the principle surface 112a of the second angle correcting plate 112, is denoted by A, it is thought that a good effect can be obtained if the shape of the second angle correcting plate 112 is determined so as to satisfy the following relation formula (1).

{(45°/(angle ∠ABC)}×(distance AB)≦L (1)

Incidentally, one example of a second angle of the present invention corresponds to the ∠A₁B₁C shown in FIG. 7 of the present embodiment, and one example of a second distance of the present invention corresponds to the length of the line segment A₁B₁ shown in FIG. 7.

As described above, especially in a case where the reactant gas is introduced or the like, it is hard to keep the degree of vacuum during the deposition low. In this case, it becomes impossible to disregard existence of the evaporation particles which enter from a direction opposite to a target viewed from the substrate. The influence of the evaporation particle with such undesirable components of the evaporation particles is not considered enough conventionally, for example, in a case of constitution such as the patent document whose Japanese Patent Laid-open Number is 2003-13206, the evaporation particles with such undesirable components of the evaporation particles can not be removed. On this point, the present invention has a completely different feature from the invention disclosed by the patent document whose Japanese Patent Laid-open Number is 2003-13206.

Moreover, in the case of mixed gases, a mean free path in the total pressure about the gas kind with the highest partial pressure would be used.

Moreover, when the gas introduction is not performed positively, the mean free path in the total pressure about H₂O, which usually has the highest existence ratio among the residual gases, would be used.

Incidentally, the case of sputtering has been described in the present embodiment, however, also in other deposition methods, such as, for example, a vacuum deposition method, the present invention has the same effect.

Moreover, it has been described that the substrate 6 as a base member of the present invention was used in the above-mentioned embodiment. However, replacing with the substrate 6, a sheet-like member 70, such as a film of PET or PEN, and a metallic foil may be utilized.

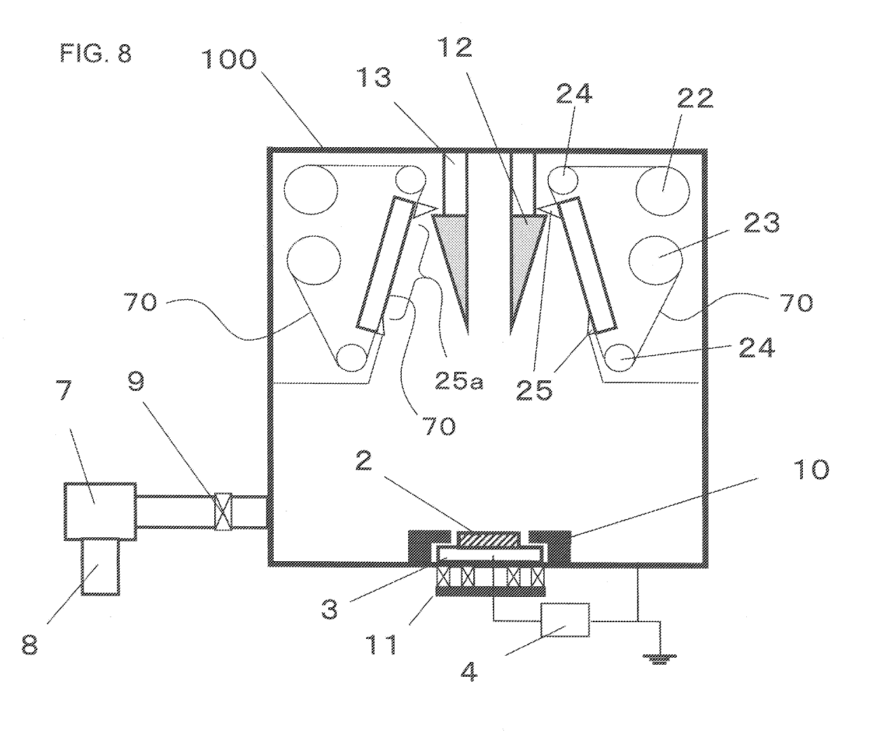

A schematic view of a deposition apparatus in this case is shown in FIG. 8. Here, FIG. 8 is a schematic front view of a deposition apparatus as a modified example of the Embodiment 1, the elements similar to those shown in FIG. 1 are denoted with the same reference numerals, and the descriptions thereof will be omitted.

As shown in FIG. 8, the sheet-like member 70 is supplied from a feed roll 23, passes through the roll 24 and is wound up by a wind roll 22. The surface of the sheet-like member 70 is deposited when it passes through an opening part 25a of a mask 25, it is possible to perform the deposition by the evaporation particles whose incident angles are controlled properly likewise the case of the stationary substrate 6 explained in the above-mentioned embodiment.

### Embodiment 2

In the following, Embodiment 2 of the present invention will be described.

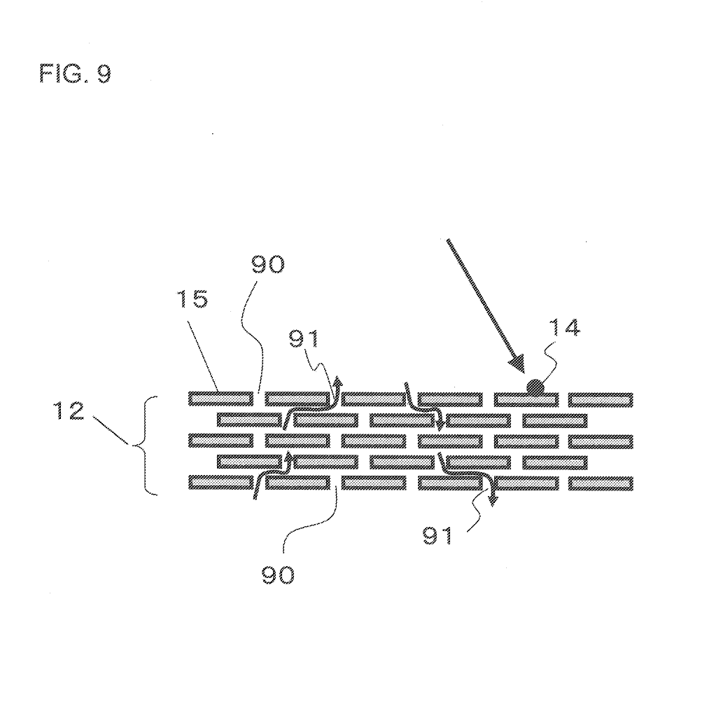

In this embodiment, the case, where the above-mentioned angle correcting plate 12 or the second angle correcting plate 112 is constituted by a plurality of correcting members provided with holes or a plurality of correcting members provided with meshes or slits, will be described referring to FIG. 9.

Here, FIG. 9 is a schematic view illustrating a constitution example of an angle correcting plate which is constituted by a plurality of correcting members according to the present Embodiment 2.

Since the constitution of the deposition apparatus itself is the same as the case of the above-mentioned Embodiment 1, the explanation will be omitted.

The above-mentioned angle correcting plates 12 and 112 are not limited by their constitution as long as they have structure such that the space in which the evaporation particles exist is not prepared over the substrate 6 or the sheet-like member 70. More preferably, like the present Embodiment 2, the angle correcting plate 12 may be, for example, of constitution where plural correcting members 15 with holes 90 are piled up. Moreover, for example, it may be constituted by meshes, slits, or the like (not shown) in place of the correcting member provided with the holes 90.

The material of the correcting member 15 is not limited, may be metal, such as stainless steel, or may be insulating material, such as ceramic.

Moreover, the diameter of the hole 90 may be, for example, φ around 10 mm as long as gas 91 can pass. Similarly, the slit may be, for example, around 5 mm in width, around 30 mm in length. According to these, although passage of the evaporation particle 14 (refer to FIG. 9) is barred, the passage of the gas 91 is enabled freely through gaps such as hole 90. It is more desirable to keep the pressure of the substrate circumference low as much as possible, in order to realize control of the incident angle by preventing dispersion due to the residual gas. Therefore, if the gas 91 is prevented from stagnating in the space which is sandwiched between the substrate 6 and the angle correcting plate 12 which is constituted by the pile of the plural correcting members 15, it becomes possible to control the incident angle more satisfactorily.

### Embodiment 3

In the following, Embodiment 3 of the present invention will be described.

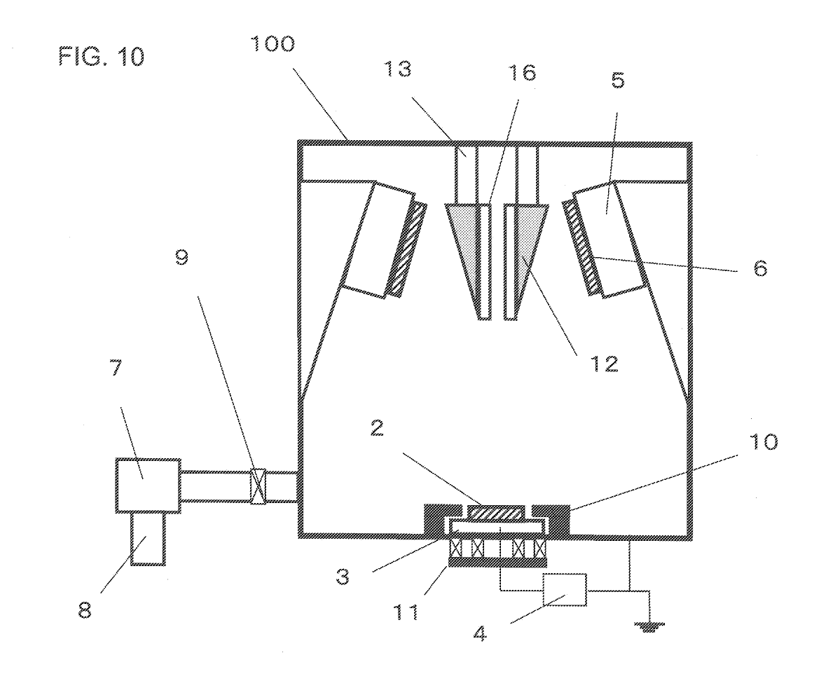

In this embodiment, the case, where the effect of preventing the evaporation particle from being disconnected by preparing a cooling mechanism at the angle correcting plate 12 is heightened, will be described referring to FIG. 10. FIG. 10 is a schematic front view illustrating a deposition apparatus which is provided with a cooling mechanism according to the present Embodiment 3.

Since the constitution of the deposition apparatus itself is the same as the case of the above-mentioned Embodiment 1, the explanation will be omitted.

As shown in FIG. 10, a cooling mechanism 16 is provided at a portion which touches the angle correcting plate 12. During performing the deposition, the rise in heat of the inside of the vacuum chamber 100 occurs due to the heat input from plasma, the deposition heat of the evaporation particles, and the like. The temperature of the angle correcting plate 12 becomes high similarly, and at this time, adsorbed gas is released from the surface. Moreover, when the temperature of the angle correcting plate 12 becomes very high, a part of the evaporation particles which arrived at the surface may also be reflected, or the evaporation particles attached to the surface may be disconnected. Since such reflected evaporation particles, the gas released from the angle correcting plate 12, and the like cause a change of the incident angle by colliding with other evaporation particles, they are not desirable.

On the other hand, since degasification from the surface of the angle correcting plate 12 can be prevented by providing the cooling mechanism 16 for preventing and controlling the rise in heat of the surface temperature of the angle correcting plate 12, it becomes possible to control the incident angle satisfactorily.

### Embodiment 4

In the following, Embodiment 4 of the present invention will be described.

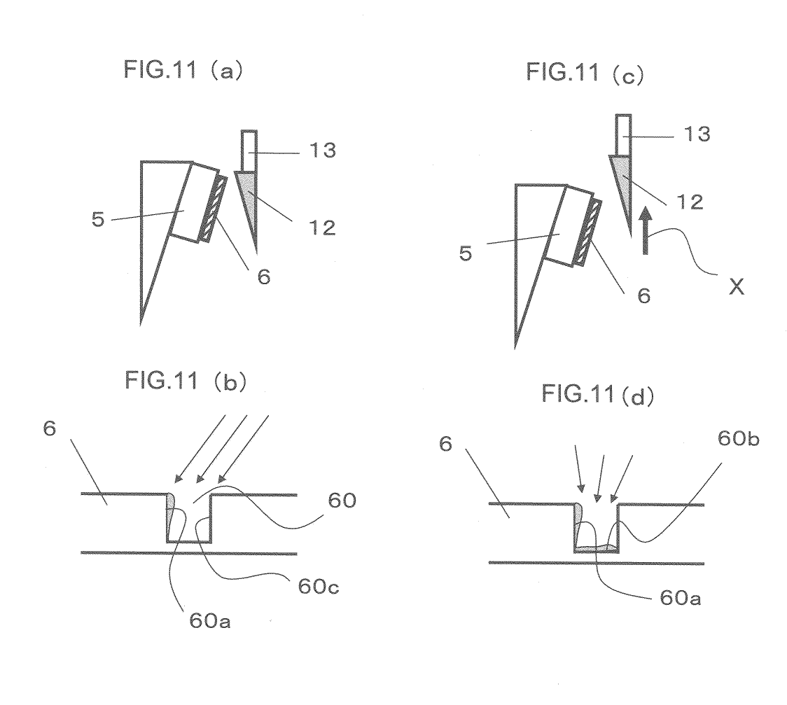

In this embodiment, the deposition method, in which the deposition is performed by changing a position of the angle correcting plate 12 several times or continually, will be described using FIG. 11 (a) to FIG. 11(d). Here, FIG. 11 (a) and FIG. 11(c) are schematic views illustrating the situation before movement of the angle correcting plate 12 and that after the movement. FIG. 11 (b) is a schematic view illustrating a region of deposition in the situation before the movement of the angle correcting plate 12, and FIG. 11 (d) is a schematic view illustrating a region of deposition in the situation after the movement of the angle correcting plate 12.

Since the fundamental constitution of the deposition apparatus is the same as the case of the above-mentioned Embodiment 1, the explanation will be omitted.

First, the deposition is performed on the first deposition condition.

In the first deposition condition, the positional relationship between the angle correcting plate 12 and the substrate 6 is in the situation described in the above-mentioned Embodiment 1 (refer to FIG. 11(a)). In this situation, the incident angles of the evaporation particles are only components near to the angle of an aim, and, thereby, the deposition can be performed. Thus, in the case of performing deposition, for example, to via 60 such as the example of FIG. 11 (b), the deposition to sidewall 60a can be performed by the deposition particles which enter aslant.

Moreover, if a rotating mechanism is provided at the substrate holder 5, the deposition can also be performed all through a side wall 60c on the opposite side, namely, on the whole side wall.

Next, the deposition is performed on the second deposition condition.

At this time, the positional relationship between the angle correcting plate 12 and the substrate 6 is different from the situation shown in FIG. 11(a). As shown in FIG. 11(c), the angle correcting plate 12 is moved in the direction going away from the evaporation source (refer to an upward thick arrow X of FIG. 11(c)). By means of this, as for the angle distribution of the evaporation particles which enter into the substrate 6, the component which carries out vertical incidence to the substrate 6 increases, and the deposition becomes to be performed mainly at a bottom 60b of the via 60 (refer to FIG. 11 (d)). As the first deposition condition and the second deposition condition, by adjusting the deposition time in addition to the movement distance of the angle correcting plate 12 mentioned above, it becomes possible to make film thickness for the side wall 60a of the via 60 equal to the film thickness for the bottom 60b.

Like this, the first deposition condition and the second deposition condition can change the deposition range and its film thickness for a solid object, and can improve coating characteristics for the via inside by repeating them in turn.

Moreover, in the embodiment of the present invention, an example about the two deposition conditions was shown. However, the number of the deposition condition is not limited to two, and it is also effective to move the angle correcting plate 12 continuously with non step. The examples of the deposition for the inside of the via were described, and also the case of deposition for an uneven solid object has the same effect.

Moreover, in the above-described embodiment, a case where the incident angle of the evaporation particle was 65° was described. However, the present invention is not limited to this, even if it is a case of another incident angle, the present invention can be applied, and the same effect as the above is exerted. In this case, the angle of a peak shift can be found by performing the simulation explained in FIG. 6 with respect to another incident angle, and based on the fund angle, another angle ∠ABC corresponding to ∠ABC=45° used in the above-mentioned embodiment can be obtained. Thereby, the shape of the angle correcting plate can be determined.

Moreover, in the above-described embodiment, a case where the incident angle was 65° was described. However, the present invention is not limited to this, even if the incident angle of 65° had some variations, ∠ABC=45° obtained based on the simulation explained in FIG. 6 is applicable as it is, and the same effect as the above is exerted.

Moreover, in the above-described embodiment, a case where the substrate or the film-like member as one example of a base member of the present invention was used was described. However, the present invention is not limited to this, even if it is a case where the deposition is performed on evaporation subjects except the substrate and the film-like member (for example, complicated solid shape objects, such as a mold, a tool, and the like), the present invention can be applied.

### INDUSTRIAL APPLICABILITY

A deposition apparatus and a deposition method of the present invention have an effect that it is possible to suppress the evaporation particles incident to a substrate at an inappropriate angle and realize a deposition with the evaporation particles of the desired incident angle, and are useful to various deposition apparatuses and deposition methods of emitting evaporation particles from the evaporation source and performing the deposition.

### DESCRIPTION OF SYMBOLS

1, 100 vacuum chamber
2 target
3 back plate
4 high-voltage impression power supply
5 substrate holder
6 substrate
7 exhaust apparatus
8 exhaust opening
9 valve
10 ground shield
11 magnetic circuit
12 angle correcting plate
13 moving mechanism
14 evaporation particle
15 correcting member
16 cooling mechanism
17 evaporation particle flux
18 accumulated film
21 evaporation source
22 wind roll
23 feed roll
24 roll
25 mask
25a opening portion
70 sheet-like member

1. A deposition apparatus comprising:
a vacuum chamber;
a holding part which holds a base member in the vacuum chamber;
an evaporation source which has a principal surface inclined with respect to a principal surface of the base member which is held, and holds a deposition material; and
an angle correcting member which is provided so as to cover an upper space of the principal surface of the base member, and is provided outside a spatial region which is encompassed by line segments which connect a periphery of the principal surface of the evaporation source and a periphery of the principal surface of the base member, wherein
the principal surface of the base member, the principal surface of the evaporation source and a principal surface facing the base member, of the angle correcting member, extend to a depth direction in a case of viewing from a front of the vacuum chamber,
when an arbitrary point on the principal surface of the base member is denoted by a first point and at least a center point on the principal surface of the evaporation source is denoted by a second point in a case of viewing from the front of the vacuum chamber,
at least a part of the principal surface of the angle correcting member exists on each line which forms 45° from the respective first points with respect to each line which connects the respective first points and the second point, and another part of the principal surface of the angle correcting member extends to a side opposite to the evaporation source.

2. The deposition apparatus according to claim 1, wherein
at least the part of the principal surface of the angle correcting member exists at a position of a mean free path of water molecules or less away from the respective first points.

3. The deposition apparatus according to claim 2, wherein
the other part of the principal surface of the angle correcting member exists on each line which forms a second angle which is more than 45°, from the respective first points, to each line which connects the respective first points and the second point, exists at a position of a second distance which is more than the mean free path of water molecules away from the respective first points, and a relation formula, which is {(45°/(the second angle)}×(the second distance)≦the mean free path, is established.

4. The deposition apparatus according to claim 1, wherein
the angle correcting member is constituted by a plurality of members provided with holes or a plurality of members provided with meshes or slits.

5. The deposition apparatus according to claim 1, wherein
the angle correcting member is provided with a cooling mechanism.

6. The deposition apparatus according to claim 1, wherein
the angle correcting member is movable with respect to the base member during deposition.

7. A deposition method for a deposition apparatus which comprises a vacuum chamber, a holding part which holds a base member in the vacuum chamber, an evaporation source which has a principal surface inclined with respect to a principal surface of the base member which is held, and holds a deposition material, and an angle correcting member which is provided so as to cover an upper space of the principal surface of the base member, and is provided outside a spatial region which is encompassed by line segments which connect a periphery of the principal surface of the evaporation source and a periphery of the principal surface of the base member, wherein
the principal surface of the base member, the principal surface of the evaporation source and a principal surface facing the base member, of the angle correcting member, extend to a depth direction in a case of viewing from a front of the vacuum chamber,
when an arbitrary point on the principal surface of the base member is denoted by a first point and at least a center point on the principal surface of the evaporation source is denoted by a second point in a case of viewing from the front of the vacuum chamber,
regulating a direction from which the deposition material flies over with respect to the base member by using the angle correcting member in which at least a part of the principal surface of the angle correcting member exists on each line which forms 45° from the respective first points with respect to each line which connects the respective first points and the second point, and another part of the principal surface of the angle correcting member extends to a side opposite to the evaporation source.

8. The deposition method according to claim 7, wherein
at least the part of the principal surface of the angle correcting member exists at a position of a mean free path of gas or less, which is introduced in the vacuum chamber, or a mean free path of water molecules or less, which exist in the vacuum chamber, away from the respective first points.

9. The deposition method according to claim 8, wherein
the other part of the principal surface of the angle correcting member exists on each line which forms a second angle which is more than 45°, from the respective first points, to each line which connects the respective first points and the second point, exists at a position of a second distance which is than the mean free path of water molecules away from the respective first points, and a relation formula, which is {(45°/(the second angle)}×(the second distance)≦the mean free path, is established.

10. The deposition method according to claim 7, wherein
the angle correcting member is constituted by a plurality of members provided with holes or a plurality of members provided with meshes or slits.

11. The deposition method according to claim 7, wherein
the angle correcting member is provided with a cooling mechanism, and
performing deposition while cooling a temperature of the angle correcting member.

12. The deposition method according to claim 7, wherein
the angle correcting member is movable with respect to the base member during deposition, and
performing deposition while changing an incident angle distribution of an evaporation particle to the base member by moving a position of the angle correcting member to a different position and performing deposition at the respective positions.
